(19) United States
(12) Patent Application Publication
(10) Pub. No.: US 2026/0219207 A1
(43) Pub. Date: Jul. 30, 2026

(54) ILLUMINATION SYSTEM FOR A MASK INSPECTION SYSTEM

(71) Applicant: Carl Zeiss SMT GmbH, Oberkochen (DE)

(72) Inventors: Eugen Anselm, Aalen (DE); Tobias Hegele, Aalen (DE)

(21) Appl. No.: 19/459,452

(22) Filed: Jan. 26, 2026

(30) Foreign Application Priority Data
Jan. 30, 2025 (DE) 102025103346.3

(51) Int. Cl. G01N 21/956; G02B 5/08; G02B 5/10; G02B 26/08; G03F 1/84; G03F 7/00

(52) U.S. Cl. CPC G01N 21/956; G02B 5/0891; G02B 5/10; G02B 26/0816; G03F 1/84; G03F 7/7085; G01N 2021/95676; G01N 2201/0636

(57) ABSTRACT

An illumination system comprising an illumination optics unit is part of a mask inspection system for use with EUV illumination light. A beam homogenization device serves for guiding the illumination light. A guidance of the illumination light via the beam homogenization device is designed with at least one displaceable optics component such that the illumination light is guided via an illumination light sub-channel which varies within an illumination overall channel on account of the displaceable optics unit. The illumination light overall channel is specified by the illumination system for the illumination light. The result is an illumination system with optimized utilization efficiency for the EUV illumination light.

### CROSS-REFERENCE TO RELATED APPLICATION

The present patent application claims the priority of German patent application DE 102025103 346.3, filed on January 30, 2025, the contents of which are incorporated herein by reference in their entirety.

### TECHNICAL FIELD

The invention relates to an illumination system for a mask inspection system for use with EUV illumination light. Furthermore, the invention relates to an optical system comprising such an illumination system, and to a mask inspection system comprising such an optical system.

### BACKGROUND

A mask inspection system is known from US 10,042,248 B2, DE 10220815 A1 and WO 2012/101269 A1. DE 10 2013 212 613 A1 discloses an illumination optics for a metrology system. DE 10 2008 042 462 A1 discloses an illumination system for EUV microlithography. DE 100 01 291 A1 discloses a mirror to reflect EUV light.

### SUMMARY

It is an aspect of the present invention to develop an illumination system for such a mask inspection system in such a way that a utilization efficiency for the EUV illumination light is optimized.

This aspect is achieved according to the invention by an illumination optics unit having the features specified in Claim 1.

According to the invention, it has been recognized that a displaceable optics component which variably guides an illumination light sub-channel offers the possibility of bringing about a beam homogenization in particular on account of a corresponding averaging effect with regard to a varying direction and/or with regard to a varying channel width of the varyingly guided illumination light sub-channel.

The illumination light overall channel, firstly, and the illumination light sub-channel, secondly, are in particular geometric beam paths, i.e., portions of a beam path of the EUV illumination light which is predefined in particular by marginal aperture boundaries between an EUV light source and an object field of the illumination system that can be illuminated by use of the illumination optics unit.

In particular, a hollow waveguide for beam homogenization can be dispensed with. Alternatively, such a hollow waveguide can be used in addition to the displaceable optics component for further intensity homogenization of the illumination light.

A numerical aperture of the illumination light sub-channel can be smaller than the numerical aperture of the illumination light overall channel. A ratio of the numerical apertures between the illumination light sub-channel, firstly, and the illumination light overall channel, secondly, can be at least 1:1.1 and can be, for example, in the range of between 1:1.1 and 1:10. Alternatively or additionally, the illumination light sub-channel can have a varying numerical aperture depending on a displacement position of the displaceable optics component. A maximum numerical aperture of such an illumination light sub-channel varying with regard to the numerical aperture may equal the numerical aperture of the illumination light overall channel.

The displaceable optics component can be designed variably such that, on average over time, the illumination light overall channel is illuminated overall with the illumination light. This temporal averaging ensures an intensity homogenization of the illumination light in the downstream beam path to an object field or illumination field of the mask inspection system.

A mirror as a displaceable optics component can be formed by a collector mirror and/or by a downstream mirror guiding the illumination light to the object field. Such a mirror can serve as an input-coupling mirror for an additional beam homogenization device, which is then likewise part of the illumination optics unit.

A part of the EUV light source can also be used in combination with a likewise displaceable, downstream mirror for direction variation of the illumination light sub-channel.

Depending on the embodiment of the illumination optics unit, a first and/or a second and/or a third mirror for guiding the illumination light downstream of an EUV light source can be embodied as a displaceable optics component as part of the beam homogenization device. Accordingly, the illumination optics unit has at least one mirror, at least two mirrors or else at least three mirrors between the EUV light source and an output side of the beam homogenization device. One of the mirrors can be embodied as an EUV collector for collecting the illumination light emanating from a source region.

Alternatively or additionally, the EUV light source can be part of the illumination system. In this case, the EUV light source can be used as a displaceable optics component for direction variation of a beam guidance of the illumination light sub-channel. In this case, a source region can be used as a displaceable optics component by way of a variation of a position of a source chamber.

At least one optics component disposed downstream of the light source, firstly, and the source region, secondly, can both be used as respectively displaceable optics components and thus as parts of the beam homogenization device. The illumination system can thus have, firstly, a displaceable source region of the light source and, secondly, at least one further displaceable optics component disposed downstream of the source region.

An oscillation or wobbling frequency of an oscillation drive, which can also be embodied as an oscillation/tilt drive, according to Claim 8, leads to a particularly advantageous beam homogenization. The oscillation frequency can be greater than 500 Hz. The oscillation frequency can be in the range of between 100 Hz and 10 kHz. The oscillation frequency can be in particular in the range of between 300 Hz and 1 kHz.

A direction pattern according to Claim 9 has been found to be particularly suitable for attaining a desired beam homogenization. The variants “star”, “circle”, “rectangle” or “line” can also be realized in a manner superimposed on one another by corresponding control of the oscillation drive.

An actuator-based tiltability according to Claim 10 is also referred to as wobbling. In so far as the displaceable optics component is actuator-tiltable by at least two tilting degrees of freedom, it is possible to specify a movement pattern of a direction variation of the illumination light sub-channel by way of a frequency and/or phase relationship of a tilt over the two tilting degrees of freedom. As an alternative or in addition to the at least one tilting degree of freedom, the displaceable optics component can also be actuator-deformed and/or actuator-displaced for the direction variation of the illumination light sub-channel.

The displaceable, in particular tiltable, optics component can be a mirror, in particular an oscillating mirror. A maximum oscillation amplitude can be at most 1 mrad and can be, for example, in the range of between 0.05 mrad and 5 mrad, for example, between 0.1 and 0.2 mrad.

A beam angle limiting device according to Claim 11 avoids guidance on account of a direction variation of the illumination light sub-channel by virtue of the effect of the displaceable optics component beyond an acceptance range of downstream optical components of the illumination system. Especially an input coupling into an optionally present, downstream component of the beam homogenization device, for example, into a hollow waveguide, can then be designed effectively.

A configuration of the beam angle limiting device according to Claim 12 is particularly effective. The mirrors of the beam angle limiting device can be designed as mirrors for grazing incidence. Reflection losses can then be minimized.

An embodiment of the input-coupling mirror optics unit according to Claim 13 has proved worthwhile in particular for the input coupling of the illumination light into a downstream beam homogenization device. The ellipsoidal mirror can transfer the illumination light from a source region of the light source, arranged at one focal point, into an intermediate focus at the other focal point of the ellipsoidal mirror. The intermediate focus can be adjacent to the beam angle limiting device and/or adjacent to the beam homogenization device.

The advantages of an optical system according to Claim 14 correspond to those which have already been explained above with reference to the illumination system. This applies, mutatis mutandis, to a mask inspection system according to Claim 15.

A wafer inspection system can also be constructed accordingly. The inspection system can comprise an object holder that serves to hold the object to be inspected and is mechanically coupled to an object displacement drive, with the result that a scanning displacement of the object is possible during the illumination.

The inspection system can be a system for actinic mask inspection.

### BRIEF DESCRIPTION OF DRAWINGS

Exemplary embodiments of the invention are explained in more detail below with reference to the drawing, in which:

FIG. 1 schematically shows an optical system comprising an illumination optics unit for a mask inspection system for use with EUV illumination light;

FIG. 2 shows one embodiment of an assembly of an illumination system of the mask inspection system comprising a driven tiltable collector mirror and/or comprising a driven tiltable input-coupling mirror for input coupling of the EUV illumination light as components of a beam homogenization device of the illumination optics unit;

FIG. 3 shows, in an illustration similar to FIG. 2, the function of the driven tiltable input-coupling mirror;

FIG. 3A shows a view of a beam angle limiting device 12a with the viewing direction along an illumination beam path of the illumination system according to FIG. 3;

FIG. 4 shows, in an illustration similar to FIG. 2, the function of the driven tiltable collector mirror; and

FIG. 5 shows a schematic illustration of main components of the mask inspection system.

### DETAILED DESCRIPTION

An illumination optics unit 1 is a constituent part of an illumination system 2 of a mask inspection system for use with EUV illumination light 3. In the drawing, a beam path of the illumination light 3 is illustrated by way of marginal rays. An illumination field or object field 4 of the mask inspection system is illuminated by the illumination light 3.

The illumination light 3 is generated by an EUV light source 5 in a source region or source volume 6. The light source 5 can generate EUV used radiation in a wavelength range of between 2 nm and 30 nm, for example, in the range of between 2.3 nm and 4.4 nm or in the range of between 5 nm and 30 nm, for example, at 13.5 nm.

The light source 5 can be embodied as a plasma light source (a high-harmonic EUV source would also be possible). For example, it can be a laser plasma source (LPP; laser produced plasma) or else a discharge source (DPP; discharge produced plasma). In principle, such plasma sources are known light sources for EUV projection exposure apparatuses.

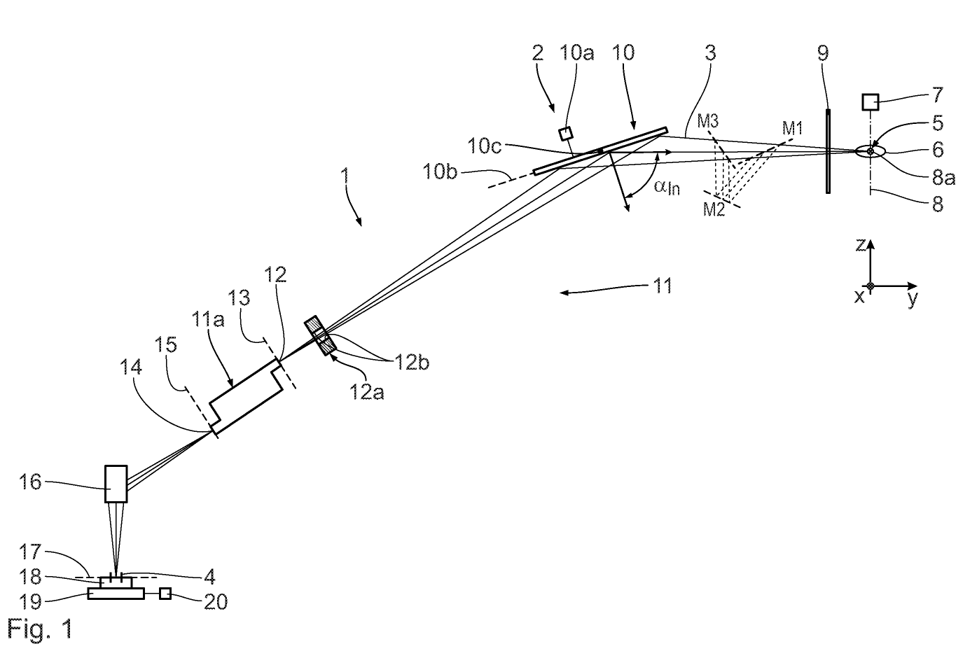

In order to facilitate positional relationships, a Cartesian xyz-coordinate system will be used hereinafter. The x-axis is perpendicular to the drawing plane of FIG. 1. The y-axis runs horizontally to the right in FIG. 1, and the z-axis runs vertically upwards in FIG. 1.

The source region 6 has an approximately ellipsoidal shape and has a greatest extent, which is also referred to as main extent, parallel to the y-axis. A main emission direction of the illumination light 3 from the source region 6 runs along this main extent, i.e., along a longest major axis of the ellipsoidal source region 6 in the case of an ellipsoidal approximation. By way of an oscillation/tilt drive 7, which acts on a source chamber of the light source 5, said source chamber not being illustrated in more specific detail in FIG. 1, the source region 6 of the light source 5 is pivotable about at least one tilt axis 8 running parallel to the z-axis. The pivot axis 8 runs transversely to the main emission direction of the illumination light 3. The thus pivotable source region 6 is part of a beam homogenization device of the illumination system, this device being explained in even greater detail below.

In particular, the oscillation/tilt drive 7 allows the source region 6 to be tilted about two tilt axes. A possible second tilt axis 8a about which the oscillation/tilt drive 7 causes tilting of the source region 6 is perpendicular to the drawing plane of FIG. 1, i.e., runs parallel to the x-axis.

The oscillation/tilt drive 7 can have at least one tilt actuator, which can be displaced linearly for generating a tilt angle. The tilt actuator can thus be embodied as a lift-tilt actuator. A travel of such a lift-tilt actuator can be in the range of between 5 µm and 1000 µm. The oscillation/tilt drive may be embodied as an electrodynamic or as a hydraulic drive. An actuator of such oscillation/tilt drive may be embodied as a piezo actuator.

A tilt angle can be of different magnitudes about the tilt axes 8, 8a involved, wherein an angle aspect ratio can be in the range of between 1:2 and 2:1, for example.

A resulting two-dimensional wobbling movement makes it possible to realize direction patterns of a direction displacement of an illumination light sub-channel within a specified illumination light overall channel in the manner of a star, in the manner of a circle, in the manner of a rectangle or else in the manner of a line. Comparable direction patterns and drive schemes to achieve those are known in particular from cathode ray tubes and from scanning devices which inter alia are known in the field of laser TV applications.

The oscillation/tilt drive 7 causes wobbling of the main emission direction of the illumination light. In this case, a wobble frequency is in the range of between 100 Hz and 10 kHz, for example, in the range of between 300 Hz and 1 kHz.

The oscillation/tilt drive 7 can be embodied with a piezo actuator, in particular as a piezo stepping drive or as a piezo linear actuator. The oscillation/tilt drive 7 can also be realized as a Lorenz actuator.

Following its emission by the light source 5, the illumination light 3 initially passes through an aperture stop 9 which marginally delimits a beam of the illumination light 3.

The aperture stop 9 can be designed to be interchangeable. For this purpose, a stop wheel can be provided, for example, which stores various aperture stop embodiments which can be used selectively in the beam path of the illumination light 3. Different input apertures of the illumination light 3 can be specified by way of such an interchangeable aperture stop design.

The aperture stop 9 can be embodied to be interchangeable and/or adjustable, and/or settable in respect of its stop boundary. Different stop geometries of the aperture stop 9 can be realized and/or adjusted as a result. For example, specifiable stop geometries can be round with a selectable diameter and/or elliptical with a selectable ellipse size and optionally with a selectable semi-axis ratio of the ellipses. Such a semi-axis ratio of an ellipse specifiable by way of the aperture stop 9 can be 2:1.

Downstream of the aperture stop 9, the illumination light beam 3 is transferred from an input-coupling mirror 10 to a beam homogenization device 11 of the illumination optics unit 1. As explained in even greater detail below, the input-coupling mirror 10 can also be part of the beam homogenization device 11. A beam-homogenizing element, for example, a hollow waveguide 11a, can be part of the beam homogenization device 11. Alternatively or additionally, the beam homogenization device 11 can also have at least one facet mirror for splitting the EUV illumination light 3 into a plurality of individual beams that are superimposed on one another for the purpose of homogenizing mixing. In this case, the beam homogenization device can also comprise, e.g., two successively arranged facet mirrors.

The aperture stop 9 limits a numerical aperture of the illumination light beam 3 emitted by the source region 6 to a value of the numerical aperture in the range of between 0.02 and 0.03, for example, in the range of between 0.02 and 0.1 or between 0.05 and 0.08. A numerical aperture as specified by the aperture stop 9 of greater than 0.1, i.e., in the range of between 0.1 and 0.3, allows a greater luminous efficiency in the illumination light beam path between the source volume 6 and the illumination field 4.

An incoherent illumination setting can be used.

As an alternative or in addition to the aperture stop 9, an aperture-limiting stop can be arranged between the hollow waveguide 11a and a downstream optical component of the illumination optics unit 1. An arrangement of such a further aperture stop in the beam path of the illumination light 3 downstream of the hollow waveguide 11a between two downstream optical components of the illumination optics unit 1 is also possible.

The input-coupling mirror 10 is embodied as exactly one ellipsoidal mirror and serves to image the source region 6 of the EUV light source 5 into an entrance opening 12 in an entrance plane 13 of the hollow waveguide 11a. A first focal point of the ellipsoidal mirror 10 is therefore located in the source region 6 and a second focal point of the ellipsoidal mirror 10 is located in the entrance opening 12 or in the region of the entrance opening 12. The ellipsoidal mirror 10 is used to focus the illumination light beam 3 into the entrance opening 12 in the entrance plane 13 of the hollow waveguide 11a. An entrance-side numerical aperture of the illumination light beam 3 upon entrance into the entrance opening 12 can range between 0.02 and 0.2, for example, be of the order of 0.15 or be of the order of 0.05 or 0.1.

Depending on the embodiment of the input-coupling optics unit, the latter has exactly one input-coupling mirror, as illustrated in FIG. 1 using the example of the input-coupling mirror 10, or else a plurality of input-coupling mirrors, e.g., two or three input-coupling mirrors.

An angle of incidence α_{In} of a central chief ray of the illumination light beam 3 at the input-coupling mirror 10 ranges between 70° and 75°. In the embodiment of the illumination optics unit 1 according to FIG. 1, the ellipsoidal mirror 10 constitutes a mirror for grazing incidence (GI).

The input-coupling mirror 10 in turn has an oscillation/tilt drive 10a, which can be embodied in the manner of the oscillation/tilt drive 7. By use of the oscillation/tilt drive 10a, wobbling of the input-coupling mirror 10 about tilt axes 10b (in the yz-plane) and 10c (perpendicular to the drawing plane of FIG. 1) is brought about. What has already been explained above with reference to the oscillation/tilt drive 7 is applicable to possible tilt angle ranges and also to oscillation frequencies of the oscillation/tilt drive 10a.

In so far as an input-coupling optics unit comprising more than one input-coupling mirror is used, it is possible to embody a first mirror in the beam path of the EUV illumination light 3 downstream of the source region 8a and optionally downstream of an EUV collector, a second mirror of the input-coupling optics unit in the beam path, a third mirror of the input-coupling optics unit or else a fourth mirror of the input-coupling optics unit in the beam path as a tiltable optics component in the manner of the input-coupling mirror 10, for example. FIG. 1 illustrates one of these variants using dashed lines, specifically the variant in which the input-coupling mirror 10 is embodied as the fourth mirror of the input-coupling optics unit in the beam path of the EUV illumination light 3 downstream of the source region 8a, specifically downstream of the first mirror M1, downstream of the second mirror M2 and downstream of the third mirror M3 in the beam path of the EUV illumination light 3 downstream of the source region 8a.

In alternative embodiments, exactly one further mirror, for example, in the manner of the mirror M1, can be arranged between the source region 8a and the input-coupling mirror 10, or else exactly two mirrors in the manner of the mirrors M1 and M2 can be arranged in the beam path of the EUV illumination light 3 downstream of the source region 8a and upstream of the input-coupling mirror 10. An EUV collector itself can also be embodied as such a displaceable optics component.

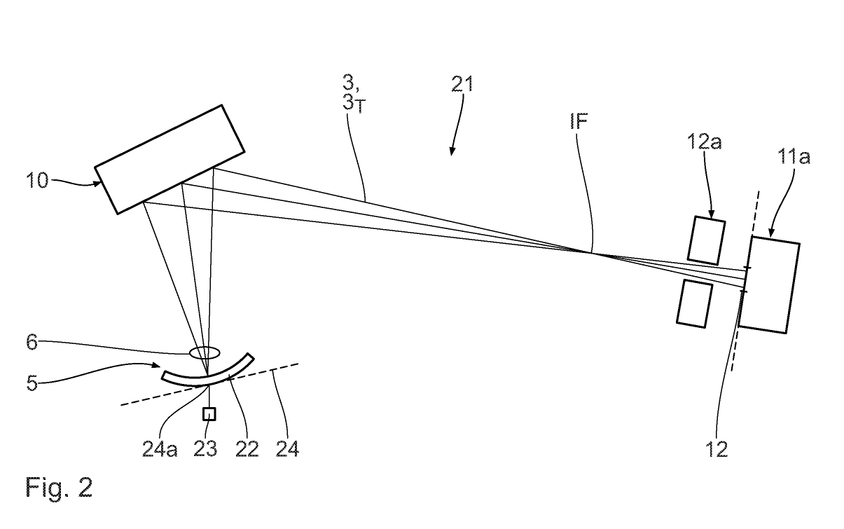

The oscillation/tilt drive 10a can also be configured so as to result in a change in shape of the input-coupling mirror 10 with a predefined (wobble) frequency. For this purpose, the oscillation/tilt drive 10a can have at least one piezoelement or else a plurality of piezoelements which are mounted on a substrate body of the input-coupling mirror 10. The at least one piezoelement of such an oscillation/tilt drive 10a causes a change in shape of the input-coupling mirror 10, thus resulting in a spatially/temporally averaged guidance of the illumination light 3, as explained below with reference to FIGS. 2 to 4.

Between the input-coupling mirror 10 and the entrance opening 12, the illumination optics unit 1 can have a beam angle limiting device 12a, the function of which is explained in even greater detail below in association with the embodiments according to FIGS. 2 to 4. The beam angle limiting device 12a can be embodied as a stop or else as a plurality of mirrors surrounding the wobbled beam of the EUV illumination light 3 for the purpose of limiting the beam angle. In such a mirror embodiment, the beam angle limiting device 12a can be embodied as at least one pair of mutually opposite mirrors. FIG. 1 shows reflection surfaces 12b of such mirrors which face the beam of the EUV illumination light 3. In addition, such a mirror embodiment of the beam angle limiting device 12a can have at least one further mirror pair with reflection surfaces which provide for a beam delimitation of the beam of the EUV illumination light 3 also along the positive and along the negative x-coordinate, i.e., perpendicular to the drawing plane of FIG. 1.

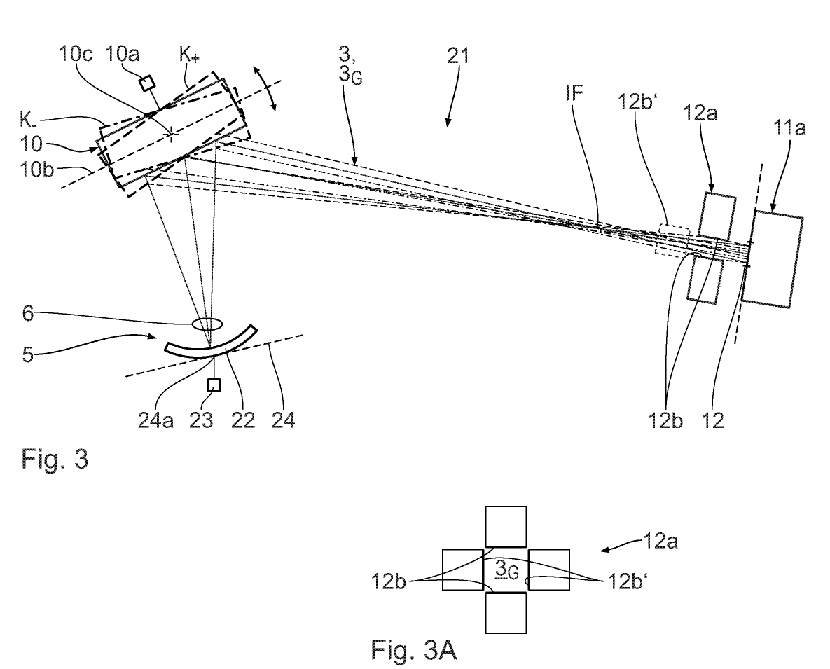

FIG. 3 and also the view according to FIG. 3A of the beam angle limiting device 12a along the illumination beam path elucidate one possible arrangement of such a further mirror pair with reflection surfaces 12b'. Between the reflection surfaces 12b, which vertically delimit the illumination light overall channel 3_{G} in FIG. 3A, and the reflection surfaces 12b', which horizontally delimit this illumination light overall channel 3_{G}, the illumination light overall channel 3_{G} is specified overall.

Along the illumination beam path, the reflection surfaces 12b, 12b' can be arranged at the same level or, as indicated using dashed lines at 12b' in FIG. 3, be axially offset with respect to one another. This applies both to the sequence of a vertical and horizontal delimitation of the

illumination light overall channel 3_{G} and to a succession of two reflection surfaces 12b for the vertical delimitation or two reflection surfaces 12b' for the horizontal delimitation of the illumination light overall channel 3_{G.}

A distance between the mirror 10 and the beam angle limiting device 12a can be in the range of between 0.5 m and 2 m and in particular in the range of between 1 m and 1.5 m.

The mirrors with the reflection surfaces 12b are embodied as mirrors for grazing incidence (grazing incidence mirrors, GI mirrors) with an angle of incidence that is greater than 45°. This angle of incidence can be greater than 60°, can be greater than 65°, and can also be greater than 70°. This angle of incidence is regularly less than 89°.

The entrance opening 12 and an exit opening 14 of the hollow waveguide 11a are square or rectangular in each case, with typical dimensions in the range of between 0.5 mm and 5 mm. An aspect ratio of the entrance opening 12 and of an identically sized exit opening 14 of the hollow waveguide 11a for the illumination light 3 in an exit plane 15 is between 0.25 and 4, for example, between 0.5 and 2. Typical dimensions of the entrance opening 12 and exit opening 14 of the hollow waveguide 11a are 0.75 mm x 0.75 mm, 1.0 mm x 2.0 mm or 1.5 mm x 2.0 mm.

An inner wall of a waveguide cavity of the hollow waveguide 11a is provided with a highly reflective coating for the illumination light 3, for example, a ruthenium coating. The waveguide cavity is cuboid, in accordance with the rectangular entrance and exit openings 12, 14. The hollow waveguide 11a has a typical length in the beam direction of the illumination light 3 in the range of between 10 and 500 mm, for example, in the range of between 20 mm and 500 mm, between 20 mm and 300 mm, or else between 20 mm and 80 mm.

Angles of incidence of the illumination light 3 on the inner wall of the waveguide cavity of the hollow waveguide 11a are greater than 60°. The illumination light 3 impinges on the inner wall with grazing incidence.

An angle between a longitudinal axis of the hollow waveguide 11a and the chief ray of the illumination light beam 3 incident into the entrance opening 12 can be 0° or can alternatively also differ from 0° and for example be in the range of between 0° and 1.5°, for example between 0.25° and 0.75°, and in particular be of the order of 0.5°.

A ratio of the length of the hollow waveguide 11a, i.e., the distance between the entrance plane 13 and the exit plane 15, and a typical diameter of the hollow waveguide 11a, i.e., the typical size or typical diameter of the entrance opening or exit opening 12, 14, ranges between 10 and 1000 and can, for example, be between 10 and 500, between 30 and 500, between 30 and 300, or else between 30 and 80 or between 200 and 500.

An imaging output-coupling mirror optics unit 16 disposed downstream of the hollow waveguide 11a and illustrated schematically in FIG. 1 images the exit opening 14, located in an exit plane 15, of the hollow waveguide 11a into the illumination field 4 in an object plane 17. This imaging can have an image-side numerical aperture in the range of between 0.1 and 0.3.

The two mirrors of the output-coupling mirror optics unit 16 can be embodied as mirrors for grazing incidence of the illumination light 3. A mean angle of incidence α1 for the input-coupling mirror 10 and respectively α2 for the at least one mirror of the output-coupling mirror optics unit 16 is greater than 60° in each case. In the case of the illumination optics unit 1, a sum α = α1 + α2 of these two mean angles of incidence is approximately 150°.

The above-explained, optionally used aperture stop downstream of the hollow waveguide 11a can be arranged between the hollow waveguide 11a and a first mirror of the output-coupling mirror optics unit 16 or else between two mirrors of the output-coupling mirror optics unit 16.

The output-coupling mirror optics unit 16 is embodied in the manner of a Wolter telescope, namely in the manner of a Type I Wolter optics unit. Such Wolter optics units are described in J. D. Mangus, J. H. Underwood “Optical Design of a Glancing Incidence X-ray Telescope,” Applied Optics, Vol. 8, 1969, page 95, and the references cited therein. In such Wolter optics units, a hyperboloid can also be used instead of a paraboloid. Such a combination of an ellipsoidal mirror with a hyperboloid mirror also constitutes a Type I Wolter optics unit.

An exemplary embodiment of the output-coupling mirror optics unit 16 is described in US 10,042,248 B2, the entire contents of which are herein incorporated by reference. Alternatively, mirrors of the output-coupling mirror optics unit 16 can also have reflection surfaces in the form of freeform surfaces.

A reticle 18 to be inspected, which is held by a reticle holder 19, is arranged in the object plane 17. The reticle holder 19 is mechanically operatively connected to a reticle displacement drive 20, by use of which the reticle 18 is displaced along an object displacement direction y during a mask inspection. In this way, a scanning displacement of the reticle 18 in the object plane 17 is possible.

The illumination field 4 has a typical dimension in the object plane 17 that is less than 1 mm and can be less than 0.5 mm. In the embodiment illustrated, the extent of the illumination field 4 is 0.5 mm in the x-direction and 0.5 mm in the y-direction.

The x/y aspect ratio of the illumination field 4 can correspond to the x/y aspect ratio of the exit opening 14.

Using a projection optics unit not illustrated in FIG. 1, the illumination field 4 is imaged into an image field in an image plane.

The image field is detected by a detection device, e.g. by one charge coupled device (CCD) camera or a plurality of CCD cameras. Regarding details of the imaging into the image field, reference is made to US 10,042,248 B2 and the references specified herein and in US 10,042,248 B2.

An inspection of a structure on the reticle 18, for example, is possible by use of the mask inspection system.

An image recording frequency of the detection device can be in the range of between 10 Hz and 100 Hz, i.e., is typically less than a wobble frequency of the oscillation/tilt drives 7 and/or 10a by a factor of 5 to 50 and in particular by a factor of 10 to 25.

An imaging factor β₁ of the input-coupling mirror optics unit 10 can be in the range of between 0.1 and 50, i.e., its action can vary from a reduction by a factor of 10 to a magnification by a factor of 50. An imaging factor β₂ of the output-coupling mirror optics unit 16 can be in the range of between 0.02 and 10, i.e., its action in turn can vary from a reduction by a factor of 50 to a magnification by a factor of 10. In the case of the illumination optics unit 1, a product β₁, β₂ of the two imaging factors can range between 0.25 and 10.

FIG. 2 shows a further embodiment of an illumination system 21 which can be used instead of corresponding components of the illumination system 2. Components and functions corresponding to those which have already been explained above with reference to the illumination system 2 according to FIG. 1 bear the same reference signs, in particular, and will not be discussed in detail again.

The illustration shows a beam path of the beam homogenization device 11 between the source region 6 of the light source 5 and the entrance opening 12 of the hollow waveguide 11a. The illustration shows an illumination light sub-channel 3_{T} of the EUV illumination light 3, which is guided by the optical components according to FIG. 2 in the instantaneous position thereof.

In the embodiment according to FIG. 2, an EUV collector 22 embodied as an ellipsoidal mirror is disposed downstream of the source region 6 in the beam path of the EUV illumination light 3. The source region 6 is located at one focal point of the collector mirror 22. An intermediate focus IF is located at the other focal point of the collector mirror 22. This intermediate focus IF can, as illustrated in FIG. 2, lie in the beam path between the input-coupling mirror 10 and the entrance opening 12 of the hollow waveguide 11a. Alternatively, the intermediate focus IF can also be located in the region of the entrance opening 12.

FIG. 3 shows an effect of the oscillation/tilt drive 10a with regard to a wobbling tilt of the input-coupling mirror 10 about the tilt axis 10c. In addition to an initial tilting state of the input-coupling mirror 10 (cf. FIG. 2), a maximum oscillation amplitude of the input-coupling mirror 10 in both tilting directions about the tilt axis 10c is also illustrated in FIG. 3. In addition to the beam guidance of the illumination light sub-channel 3_{T} of the EUV illumination light 3 in the initial state according to FIG. 2, FIG. 3 also illustrates beam paths of further illumination light sub-channels of the EUV illumination light 3 upon reflection at the input-coupling mirror 10 upon attainment of the two maximum oscillation amplitudes illustrated, which complement one another to form an illumination light overall channel 3_{G}.

At maximum oscillation amplitude in the anticlockwise direction in FIG. 3 (position K₊), the reflection surface 12b of the upper mirror of the beam angle limiting device 12a upstream of the entrance opening 12 in FIG. 3 is effective, so that despite the deflection of the beam of the EUV illumination light 3 in this tilt position K₊ the beam is directed into the entrance opening 12 of the beam homogenization device 11.

Accordingly, at the other maximum oscillation amplitude (position K₋), the lower reflection surface 12b of the corresponding mirror of the beam angle limiting device 12a in FIG. 3 is effective for guiding the correspondingly deflected beam of the EUV illumination light 3 into the entrance opening 12.

Over the entire tilt amplitude of the input-coupling mirror 10 about the tilt axis 10c between the maximum tilt positions K₊ and K₋, the reflection surfaces 12b of the beam angle limiting device 12a are effective for guiding the EUV illumination light 3 into the entrance opening 12, so that despite the oscillation/tilt drive 10a of the input-coupling mirror 10, the EUV illumination light 3 is guided to the entrance opening 12, i.e., does not miss the latter.

The effect of the oscillation/tilt drive 10a of the input-coupling mirror 10 is such that the illumination light 3 is in each case instantaneously guided via an illumination light sub-channel 3_{T} (cf. FIG. 2) which varies within an illumination light overall channel 3_{G} specified by the illumination system 21 for the illumination light 3, on account of the oscillatorily tilted input- coupling mirror 10, such that, on average over time, the illumination light overall channel 3_{G} is illuminated with the illumination light 3.

The collector mirror 22 has a further oscillation/tilt drive 23 for the oscillatory tilting of the collector mirror 22 about tilt axes 24 (in the yz-plane) and 24a (perpendicular to the drawing plane of FIG. 2). Tilt angles or oscillation amplitudes and oscillation or wobble frequencies of the oscillation/tilt drive 23 correspond to what has been explained above in association with the oscillation/tilt drives 7 and 10a.

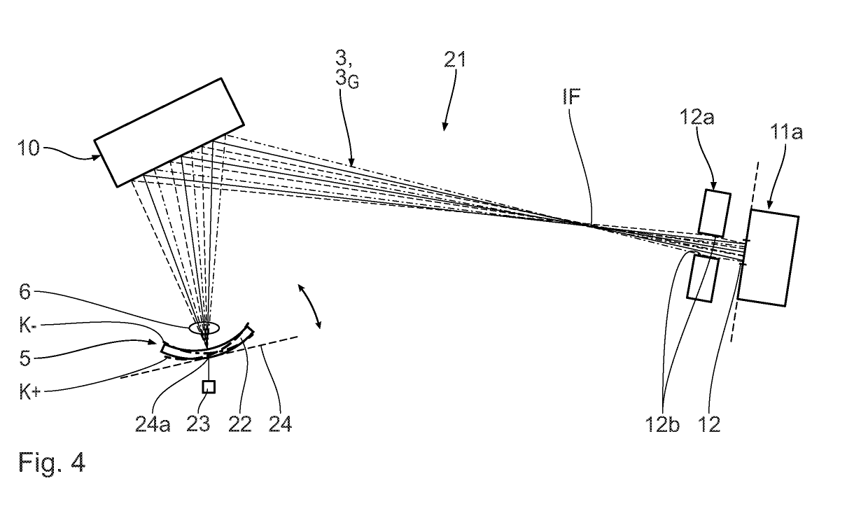

FIG. 4 illustrates, in a manner comparable to FIG. 3, a wobbling effect of the oscillation/tilt drive 23 upon oscillating-tilting of the collector mirror 22 about the tilt axis 24a. In addition to the beam path of the illumination light 3 in the initial state (illumination light sub-channel 3_{T}, cf. FIG. 2), the illustration shows the corresponding beam path of the EUV illumination light 3 upon tilting of the collector mirror 22 once again in tilt positions K₊, K₋ corresponding to the respective oscillation amplitudes in the anticlockwise and clockwise directions about the tilt axis 24a.

In the position K₊ the upper reflection surface 12b of the beam angle limiting device 12a in FIG. 4 is once again effective, in line with what has been explained above in association with FIG. 3. Accordingly, in the opposite tilt position K₋ the lower reflection surface 12b of the beam angle limiting device 12a in FIG. 4 is effective.

The effect of the oscillation/tilt drive 23 is also such that the illumination light 3 is in each case instantaneously guided via an illumination light sub-channel corresponding to the sub-channel 3_{T} according to FIG. 2, which varies within an illumination light overall channel 3_{G} specified by the illumination system 21 for the illumination light 3, on account of the oscillatorily tiltable collector mirror 22, such that, on average over time, the illumination light overall channel 3_{G} is illuminated with the illumination light 3.

The source region 6, which is oscillatorily tiltable by way of the oscillation/tilt drive 7, has a corresponding effect.

The respective displaceable optics component leads to a spatial and temporal averaging of a guidance of the illumination light 3.

The displaceable optics component can be displaced in the form of a cyclic movement.

The two variants explained above, “wobbling light source 5,” i.e. wobbling source region 6 (cf. FIG. 1) and/or “wobbling collector mirror 22” (cf. FIG. 4), and also the variant “wobbling input-coupling mirror 10” (cf. FIGS. 1 and 3), can also be combined with one another.

The displacement degrees of freedom can also be divided among the various displaceable optics components explained above. In this regard, for example, the source region 6 can be displaced along at least one degree of freedom of movement and/or the collector mirror 22 can be displaced by or along a degree of freedom of movement and/or the mirror 10 can be displaced by or along a degree of freedom of movement.

Wobble frequencies about the different tilt axes, e.g., about the tilt axes 8 and 8a, can differ from another in a specified way and can be integer multiples of one another, for example. Other frequency ratios, for example, in a range of between 1:10 and 10:1 are also possible.

An additional light mixing of the EUV illumination light 3 is provided by way of the above-explained variants for wobbling of the beam guidance of the illumination light 3 upstream of the entrance opening 12 of the beam homogenization device 11.

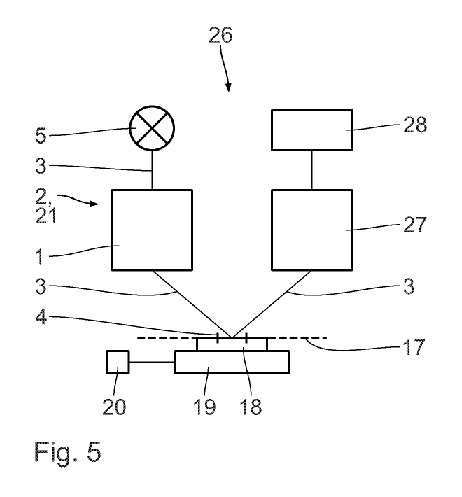

FIG. 5 shows main components of a mask inspection system 26, with the illumination system 2 or the illumination system 21 constituting part of said mask inspection system. Components and functions which have already been explained above bear the same reference signs and will not be explained in detail again.

The illumination optics unit 1 guides the illumination light 3 from the light source 5 to the object field 4. An imaging optics unit 27 guides the imaging light 3 from the object field 4 to the detection device 28. By use of the object displacement device 20, the object 18, which can be a lithographic mask or a wafer blank, can be displaced for the inspection of a region of interest (ROI). By use of the object displacement device 20, for example, an entire surface of the object 18 can be traversed and inspected. In this case, the surface of the object 18 can be traversed in particular line-by-line.

Depending on the embodiment of the illumination system 2 or 21, the beam angle limiting device 12a can simultaneously assume the function of the beam homogenization device. In this case, an additional beam homogenization device in the manner of the device 11, and in particular the hollow waveguide 11a can be dispensed with. The illumination light 3 is then guided via the beam angle limiting device 12a directly to the downstream mirrors of the output-coupling mirror optics unit 16 and to the object field 4.

A number of embodiments of the invention have been described. Nevertheless, it will be understood that various modifications can be made without departing from the spirit and scope of the invention. For example, the shapes, geometry, and/or dimensions of various components of the illumination optics unit 1, the illumination system 2, and/or the mask inspection system can be different from those described above.

While some embodiments, examples or aspects described herein include some but not other features included in other embodiments, examples or aspects combinations of features of different embodiments, examples or aspects are meant to be within the scope of the claims, and form different embodiments, as would be understood by those skilled in the art. The embodiments of the present invention that are described in this specification and the optional features and properties respectively mentioned in this regard should also be understood to be disclosed in all combinations with one another. The description of a feature comprised by an embodiment – unless explicitly explained to the contrary – should also not be understood such that the feature is essential or indispensable for the function of the embodiment. Accordingly, other embodiments are within the scope of the following claims.

What is claimed is:

1. An illumination system comprising an illumination optics unit for a mask inspection system for use with EUV illumination light,
comprising a beam homogenization device for guiding the illumination light,
wherein the illumination system specifies an illumination light overall channel for the illumination light,
wherein a guidance of the illumination light via the beam homogenization device is designed with at least one displaceable optics component such that the illumination light is guided via an illumination light sub-channel,
wherein the illumination light sub-channel is variable within the illumination light overall channel on account of the displaceable optics component.

2. The illumination of claim 1, wherein the displaceable optics component is configured such that, on average over time, the illumination light overall channel is illuminated overall with the illumination light.

3. The illumination system according of claim 1, comprising a mirror disposed downstream of a source region of an EUV light source that constitutes the at least one displaceable optics component.

4. The illumination system according of claim 1, comprising a displaceable first mirror for guiding the illumination light downstream of an EUV light source, and the displaceable first mirror is embodied as part of the beam homogenization device.

5. The illumination system of claim 4, comprising a displaceable second mirror for guiding the illumination light downstream of an EUV light source, and the displaceable second mirror is embodied as part of the beam homogenization device.

6. The illumination system of claim 5, comprising a displaceable third mirror for guiding the illumination light downstream of an EUV light source, and the displaceable third mirror is embodied as part of the beam homogenization device.

7. The illumination system of claim 1, comprising a source region of an EUV light source that is embodied as part of the beam homogenization device.

8. The illumination system of claim 1, wherein the beam homogenization device has an oscillation drive, which is operatively connected to the at least one displaceable optics component for generating a displacement frequency of the displaceable optics component in the range of between 100 Hz and 10 kHz.

9. The illumination system of claim 8, wherein the oscillation drive is embodied so as to realize a direction pattern of a direction displacement of the illumination light sub-channel within the illumination light overall channel
in the manner of a star,
in the manner of a circle,
in the manner of a rectangle or
in the manner of a line.

10. The illumination system of claim 1, wherein the displaceable optics component is actuator-tiltable by one tilting degree of freedom or by two tilting degrees of freedom about at least two tilt axes.

11. The illumination system of claim 1, comprising
a beam angle limiting device for limiting a beam angle of the illumination light sub-channel in the beam path upstream of the beam homogenization device,
an input-coupling mirror optics unit comprising at least one mirror for guiding the illumination light from a source region of an EUV light source to the beam angle limiting device, and
an output-coupling mirror optics unit for guiding the illumination light from the beam angle limiting device into an object field, in which an object to be inspected is arrangeable.

12. The illumination system of claim 11, wherein the beam angle limiting device has four mirrors with reflection surfaces for limiting the beam angle in four spatial directions.

13. The illumination system of claim 11, wherein the input-coupling mirror optics unit has at least one ellipsoidal mirror.

14. An optical system comprising an illumination system of claim 1 and comprising an EUV light source comprising a source region within a source chamber.

15. A mask inspection system
comprising an optical system of claim 14,
comprising a projection optics unit for imaging the object field into an image field, and
comprising a detection device for detecting the illumination light incident on the image field.

16. The mask inspection system of claim 15 wherein the displaceable optics component is configured such that, on average over time, the illumination light overall channel is illuminated overall with the illumination light.

17. The mask inspection system of claim 15 wherein the at least one displaceable optics component comprises a mirror disposed downstream of a source region of an EUV light source.

18. The mask inspection system of claim 15 wherein the beam homogenization device comprises a displaceable first mirror for guiding the illumination light downstream of an EUV light source.

19. The optical system of claim 14 wherein the displaceable optics component is configured such that, on average over time, the illumination light overall channel is illuminated overall with the illumination light.

20. The optical system of claim 14 wherein the at least one displaceable optics component comprises a mirror disposed downstream of a source region of an EUV light source.
